(19) United States
(12) Patent Application Publication
(10) Pub. No.: US 2019/0235330 A1
(43) Pub. Date: Aug. 1, 2019

(54) WIRING SUBSTRATE, DISPLAY DEVICE INCLUDING THE SAME, AND METHOD OF MANUFACTURING THE WIRING SUBSTRATE

(71) Applicant: Samsung Display Co., Ltd., Yongin-si (KR)

(72) Inventors: Keun Woo Park, Incheon (KR); Dong Il Son, Seoul (KR); Yeo Geon Yoon, Suwon-si (KR)

(21) Appl. No.: 16/045,291

(22) Filed: Jul. 25, 2018

(30) Foreign Application Priority Data
Jan. 30, 2018 (KR) 10-2018-0011143

(51) Int. Cl. G02F 1/1362; G02F 1/1333; H01L 27/12; G02F 1/1335

(52) U.S. Cl. CPC G02F 1/136286; G02F 1/133305; G02F 2001/136295; G02F 1/133602; G02F 1/133514; H01L 27/1218

(57) ABSTRACT

A wiring substrate, a display device including a wiring substrate, and a method of manufacturing a wiring substrate are provided. The display device comprises: a wiring substrate; a color conversion substrate on the wiring substrate and comprises a color conversion pattern having a wavelength shifter; and a backlight unit which is spaced apart from the color conversion substrate with the wiring substrate interposed between the backlight unit and the color conversion substrate. The wiring substrate comprises: a first base; a thin film transistor on the first base and comprising a gate electrode, an active pattern on the gate electrode, and a drain electrode and a source electrode on the active pattern and spaced apart from each other; and a wavelength-selective reflector which is disposed on the first base and stacked each other with the thin film transistor.

### CROSS-REFERENCE TO RELATED APPLICATION

This application claims priority to and the benefit of Korean Patent Application No. 10-2018-0011143, filed on Jan. 30, 2018 in the Korean Intellectual Property Office, the entire content of which is incorporated herein by reference.

### BACKGROUND

### 1. Field

One or more embodiments of the present inventive concept relates to a wiring substrate, a display device including the same, and a method of manufacturing the wiring substrate.

### 2. Description of the Related Art

With the development of multimedia, display devices are becoming increasingly important. Accordingly, various display devices such as liquid crystal display devices and organic light emitting diode display devices are being developed.

For example, a liquid crystal display device may include a liquid crystal display panel which includes field generating electrodes (such as a pixel electrode and/or a common electrode), a liquid crystal layer having an electric field formed by the field generating electrodes, and a backlight unit which provides light to the liquid crystal display panel. The liquid crystal display device displays an image by rearranging liquid crystals in the liquid crystal layer using the field generating electrodes to control the amount of light transmitted through the liquid crystal layer in each pixel.

The amount of light transmitted through the liquid crystal layer in each pixel can be controlled according to the extent to which the liquid crystals in the liquid crystal layer are rearranged. For example, if light is transmitted through an area where the rearrangement of the liquid crystals does not occur, for example, in a wiring overlap area, it can be recognized as a light leakage defect by a viewer.

In addition, if light provided from the backlight unit is unintentionally reflected within the display panel, it may not only reduce the brightness of the display device but also cause deterioration of the characteristics of elements in the display panel, thereby reducing the durability of the display device.

### SUMMARY

One or more aspects of embodiments of the present inventive concept are directed toward a display device capable of preventing or reducing light leakage and luminance reduction, thus achieving improved display quality and durability.

One or more aspects of embodiments of the inventive concept are directed toward a wiring substrate which can improve the display quality and durability of a display device.

One or more aspects of embodiments of the inventive concept are directed toward a method of manufacturing a wiring substrate which can improve the display quality and durability of a display device.

However, aspects of the present inventive concept are not restricted to the example embodiments set forth herein. The above and other aspects of the inventive concept will become more apparent to one of ordinary skill in the art to which the inventive concept pertains by referencing the detailed description of the inventive concept given below.

According to an example embodiment of the present disclosure, a display device comprises: a wiring substrate; a color conversion substrate on the wiring substrate and comprising a color conversion pattern having a wavelength shifter; and a backlight unit spaced apart from the color conversion substrate with the wiring substrate interposed between the backlight unit and the color conversion substrate, wherein the wiring substrate comprises: a first base; a thin film transistor on the first base and comprising a gate electrode, an active pattern on the gate electrode, and a drain electrode and a source electrode on the active pattern and spaced apart from each other; and a wavelength-selective reflector on the first base and stacked each other with the thin film transistor.

In an example embodiment, the wavelength-selective reflector may be composed of non-metallic inorganic materials and the wavelength-selective reflector may be in contact with one or more of the gate electrode, the active pattern, the drain electrode and the source electrode.

In an example embodiment, the wiring substrate may further comprise a gate wiring which is connected to the gate electrode and extends in a first direction, and a data wiring which is connected to the drain electrode and extends in a second direction intersecting (e.g., crossing) the first direction, and the wavelength-selective reflector may comprise a first portion which extends in the first direction and at least partially overlaps the gate wiring, and a second portion which extends in the second direction and at least partially overlaps the data wiring, wherein a width of the first portion of the wavelength-selective reflector in the second direction may be greater than a width of the gate wiring in the second direction, and a width of the second portion of the wavelength-selective reflector in the first direction may be greater than a width of the data wiring in the first direction.

In an example embodiment, the wavelength-selective reflector may comprise a first wavelength-selective reflector between the first base and the gate electrode, wherein the first wavelength-selective reflector may be configured to transmit light of a first wavelength in a visible light wavelength band and reflect light of a second wavelength, different from the first wavelength, in the visible light wavelength band to block transmission of the light.

In an example embodiment, the display device may further comprise a liquid crystal layer between the wiring substrate and the color conversion substrate, wherein the color conversion substrate may comprise a second base, the color conversion pattern on the second base, and a second wavelength-selective reflector between the color conversion pattern and the liquid crystal layer.

In an example embodiment, the color conversion substrate may further comprise a reflective polarizing layer between the second wavelength-selective reflector and the liquid crystal layer.

In an example embodiment, a reflection wavelength band of the first wavelength-selective reflector may be at least partially different from a reflection wavelength band of the second wavelength-selective reflector.

In an example embodiment, a reflection peak wavelength of the first wavelength-selective reflector may be shorter than a reflection peak wavelength of the second wavelength-selective reflector.

In an example embodiment, a transmission wavelength band of the first wavelength-selective reflector may at least partially overlap a reflection wavelength band of the second wavelength-selective reflector, a reflection peak wavelength of the first wavelength-selective reflector may be in the range of about 430 nm to about 470 nm, and the backlight unit may be configured to emit blue light having a peak wavelength in the range of about 430 nm to about 470 nm.

In an example embodiment, the first wavelength-selective reflector may comprise one or more first low refractive layers and one or more first high refractive layers stacked on each other, and the second wavelength-selective reflector may comprise one or more second low refractive layers and one or more second high refractive layers stacked on each other, wherein a total thickness of the second wavelength-selective reflector may be greater than a total thickness of the first wavelength-selective reflector.

In an example embodiment, the first wavelength-selective reflector may comprise one or more first low refractive layers and two or more first high refractive layers stacked on each other, and the second wavelength-selective reflector may comprise one or more second low refractive layers and two or more second high refractive layers stacked on each other, wherein a refractive index of each of the second low refractive layers may be substantially equal to a refractive index of each of the first low refractive layers, a thickness of each of the second low refractive layers may be greater than a thickness of each of the first low refractive layers, a refractive index of each of the second high refractive layers may be substantially equal to a refractive index of each of the first high refractive layers, a thickness of each of the second high refractive layers may be greater than a thickness of each of the first high refractive layers, one of the first high refractive layers of the first wavelength-selective reflector may be in contact with the gate electrode, and one of the second high refractive layers may be in contact with the color conversion pattern.

In an example embodiment, the first wavelength-selective reflector may have a stacked structure of an odd number of layers, and the second wavelength-selective reflector may have a stacked structure of an odd number of layers, wherein the number of layers of the second wavelength-selective reflector may be greater than the number of layers of the first wavelength-selective reflector.

In an example embodiment, the color conversion substrate may further comprise a light shielding pattern which at least partially overlaps the first wavelength-selective reflector and the second wavelength-selective reflector.

In an example embodiment, the wiring substrate may further comprise a wavelength-selective transmitter between the thin film transistor and the liquid crystal layer, wherein the wavelength-selective transmitter may be configured to transmit light of a third wavelength in a visible light wavelength band and absorb light of a fourth wavelength, different from the third wavelength, in the visible light wavelength band to block transmission of the light, and an absorption wavelength band of the wavelength-selective transmitter may at least partially overlap a reflection wavelength band of the first wavelength-selective reflector.

In an example embodiment, the wavelength-selective reflector may comprise a third wavelength-selective reflector on the drain electrode and the source electrode and having a contact hole exposing a portion of the source electrode, and the wiring substrate may further comprise a step compensating layer on the third wavelength-selective reflector and having a contact hole connected to the contact hole of the third wavelength-selective reflector to expose a portion of the source electrode and a pixel electrode, the pixel electrode being on the step compensating layer and in contact with the source electrode, the third wavelength-selective reflector and the step compensating layer.

In an example embodiment, the wavelength-selective reflector may comprise a first wavelength-selective reflector between the first base and the gate electrode, and a third wavelength-selective reflector on the drain electrode and the source electrode, and the wiring substrate may further comprise a gate insulating layer between the gate electrode and the active pattern and in contact with the first wavelength-selective reflector and the third wavelength-selective reflector.

According to an example embodiment of the present disclosure, a wiring substrate may comprise: a base; a thin film transistor on the base and comprising a gate electrode, an active pattern on the gate electrode, and a drain electrode and a source electrode on the active pattern and spaced apart from each other; and a wavelength-selective reflector on the base and stacked each other with the thin film transistor.

According to an example embodiment of the present disclosure, a method of manufacturing a wiring substrate may comprise: forming an inorganic stack of a plurality of layers on a base; forming a conductive metal layer on the inorganic stack; forming a first mask pattern on the conductive metal layer; forming an inorganic stack pattern by patterning the inorganic stack; forming a gate wiring layer by patterning the conductive metal layer after the forming of the inorganic stack pattern; and forming an active pattern, a drain electrode and a source electrode on the gate wiring layer.

In an example embodiment, the first mask pattern may comprise a first portion having a first thickness and a second portion having a second thickness greater than the first thickness, and the forming of the inorganic stack pattern may comprise: forming a conductive metal pattern by primary etching the conductive metal layer through wet etching by using the first portion and the second portion of the first mask pattern as an etch mask; and forming an inorganic stack pattern by etching the inorganic stack through dry etching by using the first portion and the second portion of the first mask pattern and the conductive metal pattern as an etch mask.

In an example embodiment, in the forming of the inorganic stack pattern through dry etching, the first portion of the first mask pattern may be at least partially removed to form a second mask pattern which partially exposes the conductive metal pattern, and the forming of the gate wiring layer by patterning the conductive metal layer may comprise forming the gate wiring layer by secondary etching the conductive metal pattern through wet etching by using the second mask pattern as an etch mask.

Other features and aspects of example embodiments of the present disclosure may be apparent from the following detailed description, the drawings, and the claims.

### BRIEF DESCRIPTION OF THE DRAWINGS

The above and other aspects and features of example embodiments of the present disclosure will become more apparent by describing, in more detail, example embodiments thereof with reference to the attached drawings, in which:

FIG. 1 is an exploded perspective view of a display device according to an embodiment;

FIG. 2 is a layout view of pixels of a wiring substrate in the display device of FIG. 1;

FIG. 3 is a cross-sectional view of the display device of FIG. 1, taken along the line III-III′ of FIG. 2;

FIG. 4 is a cross-sectional view of the display device of FIG. 1, taken along the line IV-IV′ of FIG. 2;

FIG. 5 is a cross-sectional view of the display device of FIG. 1, taken along the line V-V′ of FIG. 2;

FIG. 6 is an enlarged view of an area A of FIG. 4;

FIG. 7 is an enlarged view of an area B of FIG. 4;

FIG. 8 exemplifies a function of a wavelength-selective reflector of the display device of FIG. 2;

FIG. 9 is a cross-sectional view of a display device according to an embodiment;

FIG. 10 exemplifies a function of a wavelength-selective reflector of the display device of FIG. 9;

FIGS. 11 and 12 are respectively cross-sectional views of display devices according to embodiments of the present disclosure; and

FIGS. 13 through 23 are views illustrating a method of manufacturing a wiring substrate according to an embodiment.

### DETAILED DESCRIPTION

Aspects and features of example embodiments of the present disclosure and methods of accomplishing the same may be understood more readily by reference to the following detailed description and the accompanying drawings. The present disclosure may, however, be embodied in many different forms and should not be construed as being limited to the example embodiments set forth herein. Rather, these embodiments are provided so that this disclosure will be thorough and complete and will fully convey the concept of the present disclosure to those skilled in the art. The present disclosure is defined by the appended claims and their equivalents.

It will be understood that when an element or layer is referred to as being “on,” “connected to,” or “coupled to” another element or layer, the element or layer can be directly on, connected, or coupled to another element or layer or intervening elements or layers may be present. When an element is referred to as being “directly on,” “directly connected to,” or “directly coupled to” another element or layer, there are no intervening elements or layers present. As used herein, connected and coupled may refer to elements being physically, electrically, and/or fluidly connected to each other.

The same reference numerals designate the same elements. As used herein, the term “and/or” includes any and all combinations of one or more of the associated listed items. Further, the use of “may” when describing embodiments of the present invention relates to “one or more embodiments of the present invention.” Expressions, such as “at least one of,” “one of,” and “selected from,” when preceding a list of elements, modify the entire list of elements and do not modify the individual elements of the list. As used herein, the terms “use,” “using,” and “used” may be considered synonymous with the terms “utilize,” “utilizing,” and “utilized,” respectively.

It will be understood that, although the terms first, second, third, etc., may be used herein to describe various elements, components, regions, layers and/or sections, these elements, components, regions, layers, and/or sections should not be limited by these terms. These terms are only used to distinguish one element, component, region, layer, or section from another element, component, region, layer, or section. Thus, a first element, component, region, layer, or section discussed below could be termed a second element, component, region, layer, or section without departing from the teachings of the invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below (e.g., both a top and a bottom orientation).

As used herein, a first direction X denotes any one direction in a plane, a second direction Y denotes a direction intersecting (e.g., crossing) the first direction X in the plane (e.g., perpendicular to the first direction X), and a third direction Z denotes a direction perpendicular to the plane. Unless otherwise defined, “plane” refers to a plane to which the first direction X and the second direction Y belong (e.g., a plane formed by the first direction X axis and the second direction Y axis). In addition, unless otherwise defined, “overlap” denotes overlapping of the elements in the third direction Z.

In this specification, element A and element B are referred to as being “stacked on each other” not only when element B is disposed (e.g., positioned) on element A, but also when element A is disposed on element B.

Hereinafter, embodiments will be described with reference to the accompanying drawings.

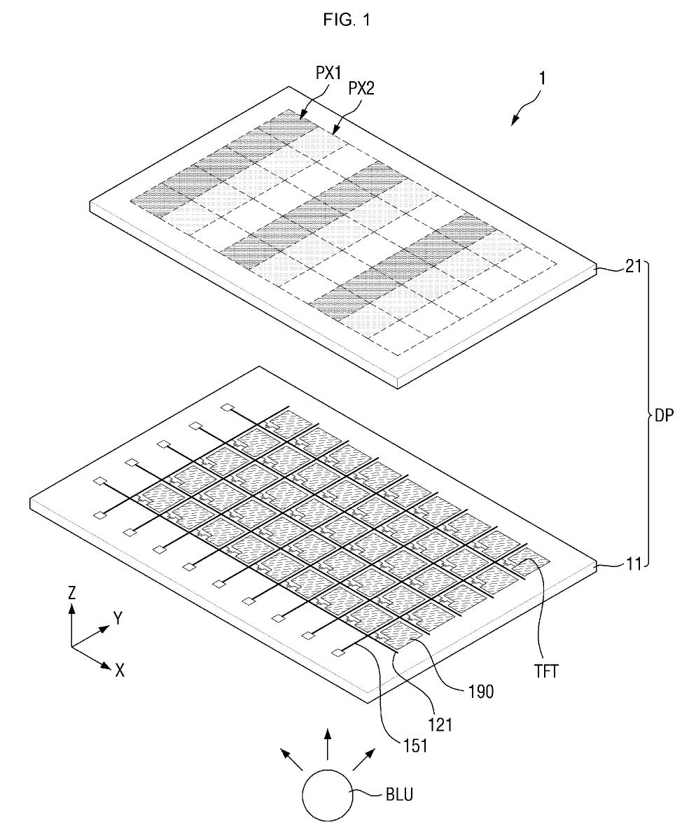

FIG. 1 is an exploded perspective view of a display device 1 according to an embodiment.

Referring to FIG. 1, the display device 1 according to the current embodiment may include a display panel DP and a backlight unit BLU.

The display panel DP may be a panel-like (e.g., planar) member including elements required for the display device 1 to display images. A plurality of pixels PX1 and PX2 arranged in a substantially matrix arrangement in plan view may be defined in the display panel DP. As used herein, “pixels” may refer to single regions into which a display area is divided in plan view for image display and color display, and one pixel may express a set or predetermined primary color. That is, one pixel may be a minimum unit region that can display a color independently of other pixels.

The pixels PX1 and PX2 may include a first pixel PX1, which displays a first color, and a second pixel PX2, which displays a second color, having a shorter peak wavelength than the first color. Hereinafter, a case where the first color displayed by the first pixel PX1 is a red color having a peak wavelength in the range of about 610 nm to about 650 nm and the second color displayed by the second pixel PX2 is a blue color having a peak wavelength in the range of about 430 nm to about 470 nm will be described as an example. However, embodiments are not limited to this example. In another example, the first color may also be a green color having a peak wavelength in the range of about 530 nm to about 570 nm.

The backlight unit BLU may overlap the display panel DP in the third direction Z and emit light having a specific wavelength toward the display panel DP. In an embodiment, the backlight unit BLU may be an edge-type (edge-kind) backlight unit including a light source module that directly emits light and a light guide plate that guides light received from the light source module toward the display panel DP.

The light source module may be a light emitting diode (LED), an organic light emitting diode (OLED), or a laser diode (LD). In an embodiment, the light source module may emit blue light of a blue wavelength band having a single peak wavelength in the range of about 430 nm to about 470 nm and provide the light of the blue wavelength band to the display panel DP.

The light guide plate may guide light received from the light source module toward the display panel DP. The material of the light guide plate is not particularly limited as long as it can guide light by inducing total reflection in the light guide plate. For example, the light guide plate may include a glass material, a quartz material, and/or a polymer material (such as polyethylene terephthalate, polymethyl methacrylate and/or polycarbonate). In other embodiment, the light guide plate may be omitted, and the backlight unit BLU may be a direct-type backlight unit including light source modules arranged to overlap the display panel DP in the third direction Z.

In one or more embodiments, one or more optical sheets may further be disposed (e.g., positioned) between the display panel DP and the backlight unit BLU. The optical sheets may include one or more of a prism sheet, a diffusion sheet, a (reflective) polarizing sheet, a lenticular lens sheet, and a micro-lens sheet. The optical sheets can improve the display quality of the display device 1 by modulating optical characteristics (e.g., condensing, diffusing, scattering, and/or polarization characteristics) of light travelling toward the display panel DP after being emitted from the backlight unit BLU.

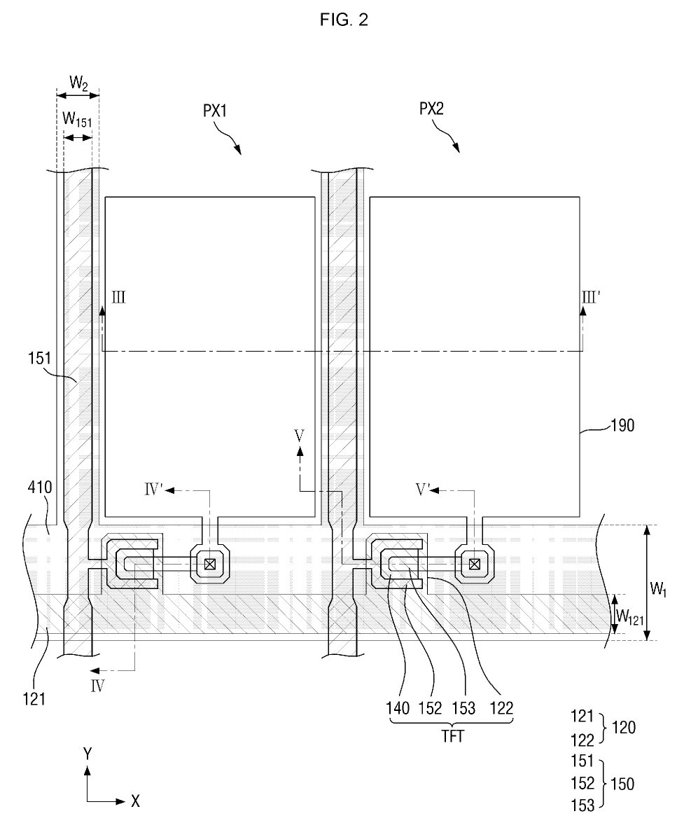

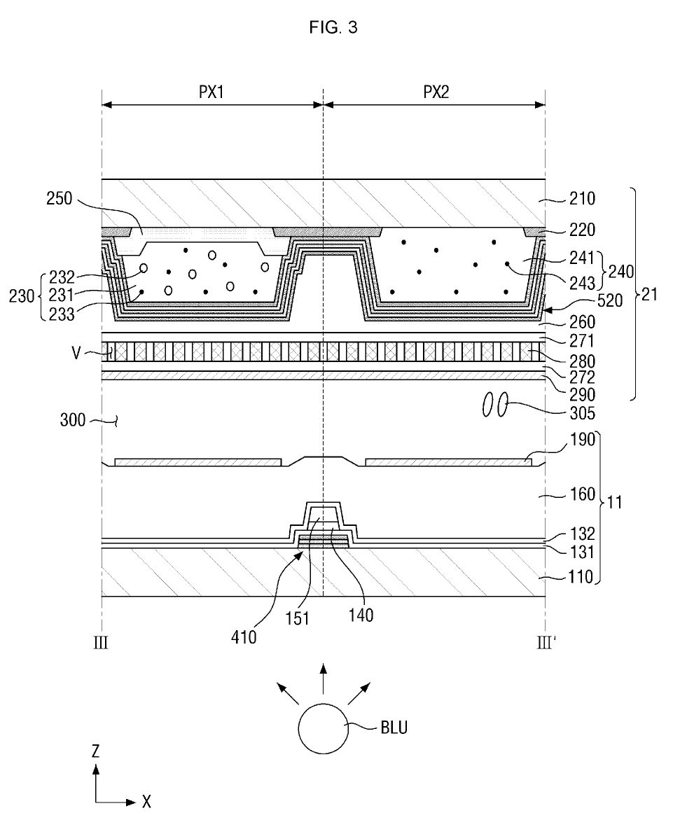

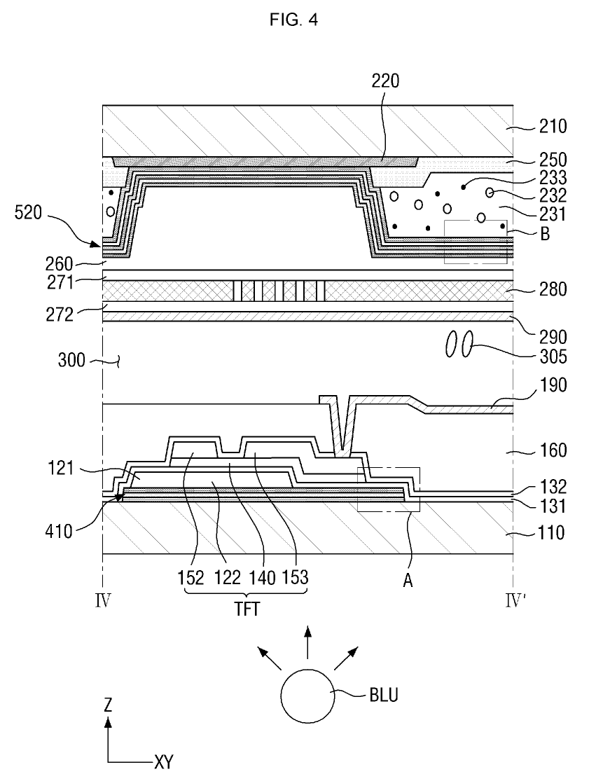

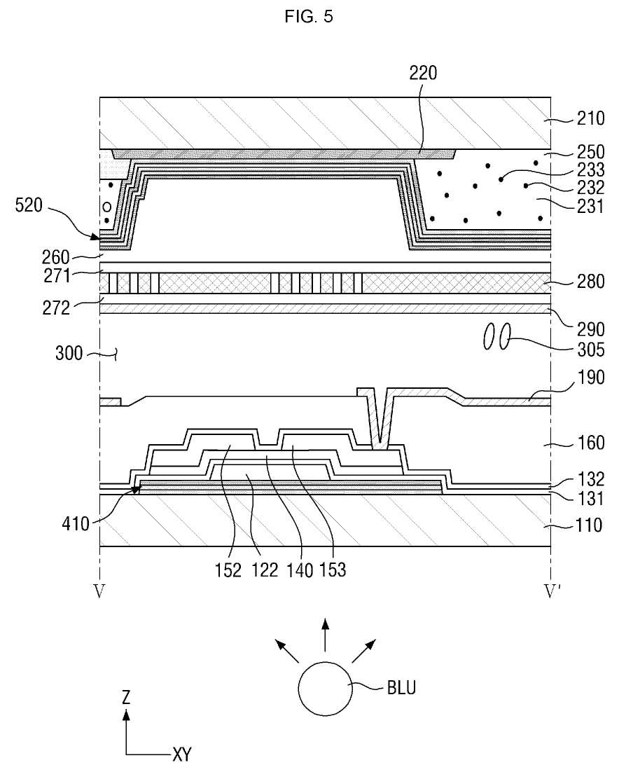

The display panel DP of the display device 1 according to the current embodiment will now be described in more detail by referring to FIGS. 2 through 5. FIG. 2 is a layout view of pixels of a wiring substrate in the display device 1 of FIG. 1. FIG. 3 is a cross-sectional view of the display device 1 of FIG. 1, taken along the line of FIG. 2. FIG. 4 is a cross-sectional view of the display device 1 of FIG. 1, taken along the line IV-IV′ of FIG. 2. FIG. 5 is a cross-sectional view of the display device 1 of FIG. 1, taken along the line V-V′ of FIG. 2.

Referring to FIGS. 1 through 5, the display panel DP may be a liquid crystal display (LCD) panel including an upper substrate 21, a lower substrate 11, and a liquid crystal layer 300 interposed between the upper substrate 21 and the lower substrate 11. The liquid crystal layer 300 may be sealed by the upper substrate 21, the lower substrate 11, and a sealing member bonding the upper substrate 21 and the lower substrate 11 together. However, the display panel DP is not limited to the LCD panel, and other display panels requiring the backlight unit BLU for image display can also be applied.

First, the lower substrate 11 will be described. The lower substrate 11 includes a lower base 110, wirings 121 and 151 and switching elements TFT, and may further include a first wavelength-selective reflector 410 stacked each other with the switching elements TFT. The lower substrate 11 may be a wiring substrate including the wirings 121 and 151 and the switching elements TFT.

The lower base 110 may provide a space on which the wirings 121 and 151 and the switching elements TFTs can be disposed. The lower base 110 may be a transparent insulating substrate or a transparent insulating film. For example, the lower base 110 may include a glass material, a quartz material, and/or a translucent plastic material. In some embodiments, the lower base 110 may be flexible, and the display device 1 may be a curved display device.

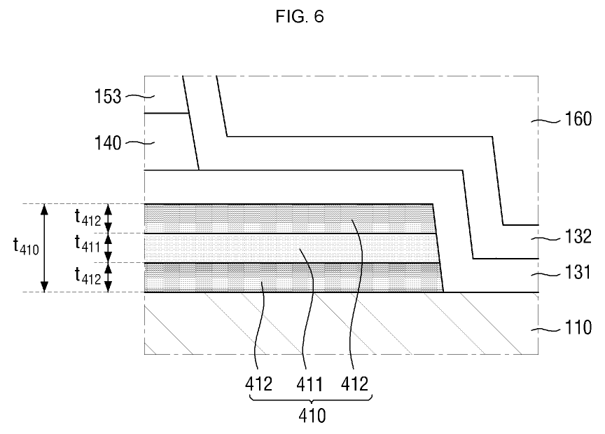

The first wavelength-selective reflector 410 may be disposed on a front surface (an upper surface in a cross-sectional view) of the lower base 110. The first wavelength-selective reflector 410 will be described in more detail later with reference to FIG. 6, etc.

A first wiring layer 120 may be disposed on the first wavelength-selective reflector 410. The first wiring layer 120 may be a gate wiring layer including a gate wiring 121 extending in the first direction X and a gate electrode 122 connected to the gate wiring 121.

The gate wiring 121 may transmit a gate driving signal, which is received from a gate driver, in the first direction X. For example, a plurality of pixels arranged along the first direction X may share one gate wiring 121. The gate electrode 122 may be connected to the gate wiring 121 to receive a gate driving signal from the gate wiring 121. The gate electrode 122 may serve as a control terminal of a switching element TFT which will be described later. In FIG. 2, the gate electrode 122 is formed integrally with the gate wiring 121 and protrudes from the gate wiring 121. However, embodiments are not limited to this case, and a portion of the gate wiring 121 can also form the gate electrode 122.

A gate insulating layer 131 may be disposed on the first wiring layer 120. The gate insulating layer 131 may be disposed over the pixels PX1 and PX2. The gate insulating layer 131 may include an insulating material so as to insulate elements disposed on the gate insulating layer 131 from elements disposed under the gate insulating layer 131. The gate insulating layer 131 may include silicon nitride, silicon oxide, silicon nitride oxide, and/or silicon oxynitride. The gate insulating layer 131 may insulate the control terminal (for example, the gate electrode 122) of the switching element TFT from a channel (for example, an active pattern 140) of the switching element TFT which will be described later.

The active pattern 140 may be disposed on the gate insulating layer 131. The active pattern 140 may include a semiconducting material. For example, the active pattern 140 may include amorphous silicon, polycrystalline silicon, and/or an oxide semiconductor. At least a portion of the active pattern 140 may overlap the gate electrode 122 to form the channel of the switching element TFT.

A second wiring layer 150 may be disposed on the active pattern 140. The second wiring layer 150 may be a source/drain wiring layer including a data wiring 151 extending in the second direction Y to transmit a data driving signal, a drain electrode 152 connected to the data wiring 151 to receive the data driving signal, and a source electrode 153 spaced apart from the drain electrode 152.

The data wiring 151 may transmit a data driving signal, which is received from a data driver, in the second direction Y. For example, a plurality of pixels arranged along the second direction Y may share one data wiring 151.

The drain electrode 152 may be connected to the data wiring 151 so as to receive a data driving signal from the data wiring 151. The drain electrode 152 may serve as an input terminal of the switching element TFT which will be described later. In FIG. 2, for example, the drain electrode 152 is formed integrally with the data wiring 151 and protrudes from the data wiring 151. However, embodiments are not limited to this case, and a portion of the data wiring 151 can also form the drain electrode 152. The source electrode 153 may be disposed on the active pattern 140 to be spaced apart from the drain electrode 152. The source electrode 153 may serve as an output terminal of the switching element TFT which will be described later. The source electrode 153 may be electrically connected to a pixel electrode 190.

The gate electrode 122, the active pattern 140, the drain electrode 152, and the source electrode 153 described above may form the switching element TFT. For example, the switching element TFT may be a thin-film transistor. The switching element TFT may be disposed in each of the pixels PX1 and PX2 and may transmit driving signals received from the wirings 121 and 151 to the pixel electrode 190 or may block the driving signals. In FIG. 4, for example, a bottom gate switching element TFT is illustrated. However, in other embodiments, the switching element TFT may be of a top gate switching element.

In some embodiments, a first protective layer 132 may be disposed on the switching element TFT. The first protective layer 132 may include an inorganic material. The first protective layer 132 may prevent or reduce the risk of the switching element TFT directly contacting an organic material, thereby preventing or reducing the deterioration of characteristics of the switching element TFT by the organic material. The first protective layer 132 may include silicon nitride, silicon oxide, silicon nitride oxide, and/or silicon oxynitride.

A step compensating layer 160 may be disposed on the first protective layer 132. The step compensating layer 160 may be disposed over the pixels PX1 and PX2. The step compensating layer 160 may minimize or reduce the steps formed by elements such as the wirings 121 and 151 and the switching element TFT disposed on the lower base 110, and provide a space in which the pixel electrode 190 is disposed. In addition, the step compensating layer 160 may insulate elements disposed under the step compensating layer 160 from elements disposed on the step compensating layer 160. That is, the step compensating layer 160 may have an insulating function as well as a planarizing function. The material of the step compensating layer 160 is not particularly limited as long as it can have a step compensating function. For example, the step compensating layer 160 may include an organic material such as acrylic resin, epoxy resin, imide resin, and/or cardo resin.

The pixel electrode 190 may be disposed on the step compensating layer 160. The pixel electrode 190 may be a field generating electrode that forms an electric field in the liquid crystal layer 300 together with a common electrode 290. The pixel electrode 190 may be disposed in each of the pixels PX1 and PX2 and may be controlled independently of other pixel electrodes 190. A different driving signal may be transmitted to each pixel electrode 190. For example, the pixel electrode 190 may be electrically connected to the output terminal (i.e., the source electrode 153) of the switching element TFT via a contact hole formed in the step compensating layer 160. The pixel electrode 190 may include a transparent conductive material. Examples of the transparent conductive material include indium tin oxide (ITO), indium zinc oxide (IZO), zinc oxide (ZnO), indium (III) oxide (In₂O₃), indium gallium oxide (IGO), and aluminum zinc oxide (AZO), but are not limited thereto. In some embodiments, the pixel electrode 190 may have slits for controlling the rearrangement direction of liquid crystals 305.

Next, the upper substrate 21 will be described. The upper substrate 21 includes an upper base 210 and a color conversion pattern 230 and may further include a second wavelength-selective reflector 520. The upper substrate 21 may be a color conversion substrate including the color conversion pattern 230.

Like the lower base 110, the upper base 210 may be a transparent insulating substrate or a transparent insulating film. For example, the upper base 210 may include a glass material, a quartz material, and/or a translucent plastic material.

A light shielding pattern 220 may be disposed on a back surface (a lower surface in a cross-sectional view) of the upper base 210. The light shielding pattern 220 may block the transmission of light by absorbing or reflecting the light. The light shielding pattern 220 may be disposed at planar boundaries between adjacent pixels PX1 and PX2 to prevent or reduce color mixing between neighboring pixels. In addition, the light shielding pattern 220 may overlap the switching element TFT and/or the like to prevent or reduce the leakage of light. For example, the light shielding pattern 220 may at least partially overlap the first wavelength-selective reflector 410 and the second wavelength-selective reflector 520, and may be in a substantially lattice shape having openings corresponding respectively to the pixels PX1 and PX2 in plan view. The light shielding pattern 220 may include an organic material containing a light shielding colorant such as a black pigment or a black dye, or may include an opaque metallic material such as chromium.

The color conversion pattern 230 may be disposed on the light shielding pattern 220. For example, the color conversion pattern 230 for converting incident light into light of the first color may be disposed in the first pixel PX1. That is, light may be converted into light of a predetermined wavelength band as it passes through the color conversion pattern 230.

The color conversion pattern 230 may include a first base resin 231 and a wavelength shifter 232 dispersed in the first base resin 231 and may further include a first scatter 233 dispersed in the first base resin 231.

The first base resin 231 is not particularly limited as long as it is a material having high light transmittance and capable of suitably dispersing the wavelength shifter 232 and the first scatter 233. For example, the first base resin 231 may include an organic material such as acrylic resin, epoxy resin, cardo resin, and/or imide resin.

The wavelength shifter 232 may convert or shift the peak wavelength of incident light to another specific (e.g., predetermined) peak wavelength. Examples of the wavelength shifter 232 include a quantum dot, a quantum rod, and a phosphor, but are not limited thereto. For example, the quantum dot may be a particulate semiconductor nanocrystalline material that emits light of a specific color when an electron transitions from a conduction band to a valence band. The quantum dot may have a specific band gap according to its composition and size. Thus, the quantum dot may absorb light and then emit light having an intrinsic wavelength. Examples of semiconductor nanocrystals of the quantum dot include group IV nanocrystals, group II-VI compound nanocrystals, group III-V compound nanocrystals, group IV-VI nanocrystals, and combinations of the same. In some embodiments, the quantum dot may have a core-shell structure including a core containing any of the above-described nanocrystals and a shell surrounding the core. The shell of the quantum dot may serve as a protective layer for maintaining semiconductor characteristics by preventing or reducing chemical denaturation of the core and/or as a charging layer for giving electrophoretic characteristics to quantum dot. The shell may be a single layer or a multilayer. Non-limiting examples of the shell of the quantum dot include a metal or a non-metal oxide, a semiconductor compound, and a combination of the same.

For example, the wavelength shifter 232 of the color conversion pattern 230 disposed in the first pixel PX1 may absorb at least a portion of blue light received from the backlight unit BLU and emit red light of a red wavelength band having a single peak wavelength in the range of about 610 nm to about 650 nm. Therefore, the first pixel PX1 in which the color conversion pattern 230 of the display device 1 is disposed can represent the first color, for example, red. In one or more embodiments, a color conversion pattern for converting transmitted light into green light may further be disposed in a green pixel of the display device 1. Therefore, the green pixel of the display device 1 can represent green. Light emitted from the wavelength shifter 232 may have a full width at half maximum (FWHM) of an emission wavelength spectrum of about 45 nm or less, about 40 nm or less, or about 30 nm or less. Therefore, the purity and reproducibility of a color displayed by the display device 1 can be further improved. In addition, the light emitted from the wavelength shifter 232 may be radiated in various directions regardless of the incident direction of incident light. This can improve the lateral visibility of the first color represented by the first pixel PX1 of the display device 1.

The first scatter 233 may have a refractive index different from that of the first base resin 231, and may form an optical interface with the first base resin 231. The first scatter 233 may be light scattering particles. The first scatter 233 is not particularly limited as long as it can scatter at least a portion of transmitted light. For example, the first scatter 233 may be metal oxide particles or organic particles. Examples of the metal oxide include titanium oxide (TiO₂), zirconium oxide (ZrO₂), aluminum oxide (Al₂O₃), indium oxide (In₂O₃), zinc oxide (ZnO), and tin oxide (SnO₂), but are not limited thereto. Examples of the organic material include acrylic resin and urethane resin, but are not limited thereto. The first scatter 233 can scatter light in various directions regardless of the incident direction of the incident light without substantially changing the wavelength of the light transmitted through the color conversion pattern 230. Accordingly, this can increase the length of the path of light transmitted through the color conversion pattern 230 and increase the color conversion efficiency of the wavelength shifter 232.

In some embodiments, a first wavelength-selective transmitter 250 may be disposed between the light shielding pattern 220 and the color conversion pattern 230 in the first pixel PX1. The first wavelength-selective transmitter 250 may be a wavelength-selective optical filter that transmits light in a specific wavelength band and absorbs or reflects light in another specific wavelength band to block the transmission of the light. For example, the first wavelength-selective transmitter 250 may be a color filter that absorbs light in a blue wavelength band and transmits light in a green wavelength band and/or light in a red wavelength band. For example, an absorption peak wavelength of the first wavelength-selective transmitter 250 may be in the range of about 430 nm to about 470 nm. In addition, a transmission wavelength band of the first wavelength-selective transmitter 250 may include a wavelength band of about 540 nm to about 550 nm and/or a wavelength band of about 610 nm to about 640 nm. Since the first wavelength-selective transmitter 250, which blocks the transmission of light in the blue wavelength band, is disposed between the color conversion pattern 230 and a viewer, a red spectrum represented by the first pixel PX1 can be made sharper, and the color purity and display quality of the display device 1 can be improved.

In some embodiments, a scattering pattern 240 may be disposed on the light shielding pattern 220 in the second pixel PX2. The scattering pattern 240 may scatter at least a portion of transmitted light. The scattering pattern 240 may include a second base resin 241 and a second scatter 243 dispersed in the second base resin 241. Like the first base resin 231, the second base resin 241 may include an organic material having high light transmittance and excellent (or suitable) dispersion characteristics. The second pixel PX2 in which the scattering pattern 240 is disposed can represent the second color, for example, the blue color substantially identical to the color of light received from the backlight unit BLU. In addition, like the first scatter 233, the second scatter 243 is not particularly limited as long as it can scatter transmitted light. For example, the second scatter 243 may include metal oxide particles or organic particles. The second scatter 243 can scatter light in various directions regardless of the incident direction of the incident light without substantially changing the wavelength of the light transmitted through the scattering pattern 240. Accordingly, this can improve the lateral visibility of the second color represented by the second pixel PX2 of the display device 1. In some embodiments, the scattering pattern 240 may further include a blue colorant, such as a blue pigment or a blue dye, dispersed or dissolved in the second base resin 241. Therefore, the spectrum of the blue color represented by the second pixel PX2 can be made sharper, and the color purity and display quality of the display device 1 can be improved.

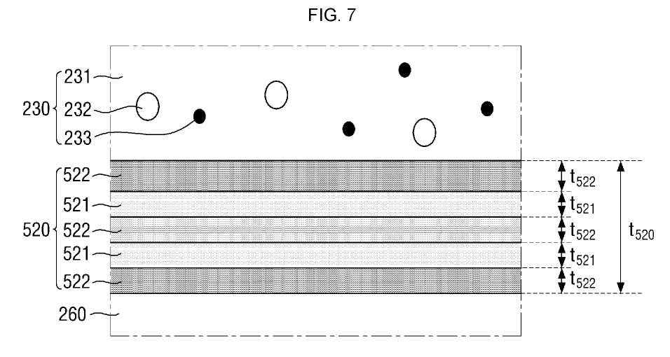

The second wavelength-selective reflector 520 may be disposed on the color conversion pattern 230 and the scattering pattern 240. The second wavelength-selective reflector 520 will be described in detail later with reference to FIG. 7, among other things.

An overcoat layer 260 may be disposed on the second wavelength-selective reflector 520. The overcoat layer 260 may be disposed over the pixels PX1 and PX2. The overcoat layer 260 can minimize or reduce the steps formed by elements, for example, the color conversion pattern 230 and the scattering pattern 240 disposed on the upper base 210. That is, the overcoat layer 260 may have a planarizing function. The material of the overcoat layer 260 is not particularly limited as long as it can have a step compensating function. For example, the overcoat layer 260 may include an organic material such as acrylic resin, epoxy resin, imide resin, and/or cardo resin.

In some embodiments, a second protective layer 271 may be disposed on the overcoat layer 260. The second protective layer 271 may include a non-metallic inorganic material. For example, the second protective layer 271 may include silicon nitride, silicon oxide, silicon nitride oxide, and/or silicon oxynitride. The second protective layer 271 may protect the overcoat layer 260 from being damaged in the process of forming a polarizing layer 280 (to be described later). Although embodiments are not limited to the following case, for example, when linear patterns of the polarizing layer 280 are formed by a dry etching process, the second protective layer 271 may function as an etch stopper to prevent the overcoat layer 260 from being unintentionally etched. In addition, the second protective layer 271 can improve the adhesion of the polarizing layer 280 to the overcoat layer 260 including an organic material, and may prevent or reduce the risk of the polarizing layer 280 being damaged or corroded by penetration of impurities such as air or moisture, thereby improving the reliability and durability of the display device 1. In other embodiments, the second protective layer 271 may be omitted, and the polarizing layer 280 may be disposed directly on the overcoat layer 260.

The polarizing layer 280 may be disposed on the second protective layer 271. Although not represented in a plan view, the polarizing layer 280 may form a wire grid pattern by including a plurality of linear patterns extending in a plane in a direction (e.g., the second direction Y). The polarizing layer 280 may function as a polarizer, for example, an upper polarizer that performs an optical shutter function together with the liquid crystal layer 300. In an embodiment, the polarizing layer 280 may have reflective polarizing properties, that is, it may reflect a polarization component oscillating in a direction substantially parallel to the direction (e.g., the second direction Y) in which the linear patterns extend and may transmit a polarization component oscillating in a direction substantially parallel to a direction (e.g., the first direction X) in which the linear patterns are spaced apart from each other. For example, the polarizing layer 280 may be a reflective polarizing layer. The linear patterns of the polarizing layer 280 may include any material that is easy to process and has excellent (or suitable) reflective characteristics. For example, the linear patterns of the polarizing layer 280 may include a metallic material such as aluminum (Al), silver (Ag), gold (Au), copper (Cu), titanium (Ti), molybdenum (Mo), nickel (Ni), and/or an alloy of the same.

A third protective layer 272 may be disposed on the polarizing layer 280. The third protective layer 272 may be disposed directly on the polarizing layer 280 to cover and protect the linear patterns of the polarizing layer 280 and to insulate the polarizing layer 280 from a common electrode 290, which will be described later. In addition, the third protective layer 272 may define a void V between adjacent linear patterns of the polarizing layer 280. The inside of the void V may be empty or filled with a predetermined gas. The third protective layer 272 may include an organic material or an inorganic material or may have a stacked structure of an organic material and an inorganic material.

The common electrode 290 may be disposed on the third protective layer 272. The common electrode 290 may be a field generating electrode that forms an electric field in the liquid crystal layer 300 together with the pixel electrode 190. The common electrode 290 may be disposed over the pixels PX1 and PX2, and a common voltage may be applied to the common electrode 290. Like the pixel electrode 190, the common electrode 290 may include a transparent conductive material.

Next, the liquid crystal layer 300 will be described. The liquid crystal layer 300 may be interposed between the lower substrate 11 and the upper substrate 21. The liquid crystal layer 300 may include a plurality of initially aligned liquid crystals 305. As used herein, “liquid crystal” may refer to a single molecule having liquid crystal properties or a collection of single molecules. In an embodiment, the liquid crystals 305 may have negative dielectric anisotropy, and their long axes may be aligned substantially perpendicularly to the plane of an initial alignment state. For example, the liquid crystals 305 may be substantially vertically aligned with a pretilt.

The first wavelength-selective reflector 410 and the second wavelength-selective reflector 520 of the display device 1 according to the current embodiment will now be described in more detail by referring to FIGS. 6 and 7. FIG. 6 is an enlarged view of an area A of FIG. 4, illustrating the first wavelength-selective reflector 410. FIG. 7 is an enlarged view of an area B of FIG. 4, illustrating the second wavelength-selective reflector 520.

First, the first wavelength-selective reflector 410 will be described. Referring to FIGS. 1 through 6, the lower substrate 11 may include the first wavelength-selective reflector 410 disposed between the lower base 110 and the switching element TFT. The first wavelength-selective reflector 410 may be in contact with the lower base 110 and the first wiring layer 120.

The first wavelength-selective reflector 410 may be a wavelength-selective optical filter that transmits light of a specific wavelength band and reflects light of another specific wavelength band to block the transmission of the light. For example, the first wavelength-selective reflector 410 may transmit 90% or more of light of a specific wavelength and reflect 90% or more of light of another specific wavelength from among light in a visible light wavelength band. In an embodiment, the first wavelength-selective reflector 410 may reflect light in the blue wavelength band and transmit light in other wavelength bands. For example, a reflection peak wavelength of the first wavelength-selective reflector 410 may be within the range of about 430 nm to about 470 nm. In addition, a transmission wavelength band of the first wavelength-selective reflector 410 may include a wavelength band of about 540 nm to about 550 nm and a wavelength band of about 610 nm to about 640 nm.

The first wavelength-selective reflector 410 may be disposed over the pixels PX1 and PX2. The first wavelength-selective reflector 410 may include a first portion extending in the first direction X and a second portion extending in the second direction Y. Thus, the first wavelength-selective reflector 410 may be of a substantially lattice shape when viewed in plan view. The first portion of the first wavelength-selective reflector 410, which extends in the first direction X, may at least partially overlap the gate wiring 121 and the switching element TFT. In addition, the second portion of the first wavelength-selective reflector 410, which extends in the second direction Y, may at least partially overlap the data wiring 151.

In a non-limiting example, the first wavelength-selective reflector 410 may completely cover the wirings, such as the gate wiring 121 and the data wiring 151, and the switching element TFT including the gate electrode 122, the active pattern 140, the drain electrode 152 and the source electrode 153. That is, the planar area occupied by the first wavelength-selective reflector 410 may be larger than the planar area occupied by the gate wiring 121, the data wiring 151 and the switching element TFT. For example, as illustrated in FIG. 2, for example, a width W₁ of the first portion of the first wavelength-selective reflector 410, which extends in the first direction X, may be greater in the second direction Y than a width W₁₂₁ of the gate wiring 121 in the second direction Y. In addition, a width W₂ of the second portion of the first wavelength-selective reflector 410, which extends in the second direction Y, may be greater in the first direction X than a width W₁₅₁ of the data wiring 151 in the first direction X.

The first wavelength-selective reflector 410 may have a stacked structure of a plurality of layers. In an embodiment, the first wavelength-selective reflector 410 may be a stack of one or more first low refractive layers 411 and one or more first high refractive layers 412 stacked alternately. For example, the first wavelength-selective reflector 410 may be an optical stack composed only of one or more first low refractive layers 411 and one or more first high refractive layers 412. The first low refractive layers 411 may have a refractive index relatively lower than that of the first high refractive layers 412, and the first high refractive layers 412 may have a refractive index relatively higher than that of the first low refractive layers 411.

The difference between the refractive indices of the first low refractive layers 411 and the first high refractive layers 412 may be about 0.4 or more or may be about 0.5 or more. For example, the first low refractive layers 411 may have a refractive index of about 1.20 to about 1.60, and the first high refractive layers 412 may have a refractive index of about 1.70 to about 2.10. The first low refractive layers 411 and the first high refractive layers 412 may each include a non-metallic inorganic material. In this case, the first wavelength-selective reflector 410 may be an inorganic stack composed of only non-metallic inorganic materials. Examples of the non-metallic inorganic materials include, but are not limited to, silicon nitride, silicon oxide, silicon nitride oxide, and silicon oxynitride. Since the first wavelength-selective reflector 410 is adjacent to the switching element TFT, more specifically, is in contact with the gate electrode 122, and is composed of non-metallic inorganic materials, the gate electrode 122 and the first wavelength-selective reflector 410 can be insulated from each other, and at the same time, it may be possible to prevent or reduce the parasitic capacitance from being formed between the wirings 121 and 151 and/or the switching element TFT and the first wavelength-selective reflector 410 in the lower substrate 11. In addition, as shown in FIG. 6, for example, a thickness t₄₁₁ of each of the first low refractive layers 411 may be smaller than a thickness t₄₁₂ of each of the first high refractive layers 412.

In some embodiments, the first wavelength-selective reflector 410 may have a stacked structure of an odd number of layers. When the first low refractive layers 411 and the first high refractive layers 412 are stacked alternately, a lowest layer of the first wavelength-selective reflector 410, which is in contact with the lower base 110, and a highest layer of the first wavelength-selective reflector 410, which is in contact with the gate electrode 122, may have the same refractive index. Since the lowest and highest layers of the first wavelength-selective reflector 410 have the same refractive index, that is, since refractive indices of an incident surface and an exit surface are matched, the first wavelength-selective reflector 410 can have efficient reflection and transmission characteristics for a specific wavelength band. For example, since the lowest layer of the first wavelength-selective reflector 410, which is in contact with the lower base 110, and the highest layer of the first wavelength-selective reflector 410, which is in contact with the gate electrode 122, are all formed as the first high refractive layers 412 having a relatively high refractive index, both the reflection characteristic and transmission characteristic of the first wavelength-selective reflector 410 can be maximized (or improved).

In FIGS. 3 through 5, the first wavelength-selective reflector 410 is composed of three layers including two first high refractive layers 412 and one first low refractive layer 411. However, embodiments are not limited to this case, and the first wavelength-selective reflector 410 can be composed of nine or more layers, eleven or more layers, or thirteen or more layers.

Next, the second wavelength-selective reflector 520 will be described. Referring to FIGS. 1 through 7, the upper substrate 21 may include the second wavelength-selective reflector 520 disposed between the color conversion pattern 230 and the overcoat layer 260. The second wavelength-selective reflector 520 may be in contact with the color conversion pattern 230 and the scattering pattern 240.

The second wavelength-selective reflector 520 may be a wavelength-selective optical filter that transmits light of a specific wavelength band and reflects light of another specific wavelength band to block the transmission of the light. For example, the second wavelength-selective reflector 520 may transmit 90% or more of light of a specific wavelength and reflect 90% or more of light of another specific wavelength among light in a visible light wavelength band. In an embodiment, a reflection wavelength band of the second wavelength-selective reflector 520 may be at least partially different from the reflection wavelength band of the first wavelength-selective reflector 410. Specifically, a reflection peak wavelength of the second wavelength-selective reflector 520 may be longer than the reflection peak wavelength of the first wavelength-selective reflector 410. In addition, the transmission wavelength band of the first wavelength-selective reflector 410 may at least partially overlap the reflection wavelength band of the second wavelength-selective reflector 520.

For example, the second wavelength-selective reflector 520 may substantially reflect light in the green wavelength band and/or light in the red wavelength band and transmit light in the blue wavelength band. The reflective peak wavelength of the second wavelength-selective reflector 520 may be in the range of about 540 nm to about 550 nm and/or in the range of about 610 nm to about 640 nm.

The second wavelength-selective reflector 520 may be disposed over a plurality of pixels, for example, over the first pixel PX1 and the second pixel PX2. Of red (or green) light emitted in various directions from the wavelength shifter 232 in the color conversion pattern 230, light emitted toward the second wavelength-selective reflector 520 may be reflected by the second wavelength-selective reflector 520 toward the upper base 210 to contribute to color display. That is, light emitted toward the back surface of the display panel DP, which cannot contribute to image display and color display, may be reflected toward the viewer by the second wavelength-selective reflector 520. This can increase the light utilization efficiency and improve the display quality (e.g., luminance and/or color purity) of the display device 1.

The second wavelength-selective reflector 520 may have a stacked structure of a plurality of layers. In an embodiment, the second wavelength-selective reflector 520 may be a stack of one or more second low refractive layers 521 and one or more second high refractive layers 522 stacked alternately. That is, the second wavelength-selective reflector 520 may be an optical stack composed only of one or more second low refractive layers 521 and one or more second high refractive layers 522. The second low refractive layers 521 may have a refractive index relatively lower than that of the second high refractive layers 522, and the second high refractive layers 522 may have a refractive index relatively higher than that of the second low refractive layers 521.

In a non-limiting example, the second low refractive layers 521 may have substantially the same refractive index as the first low refractive layers 411, and the second high refractive layers 522 may have substantially the same refractive index as the first high refractive layers 412. For example, the second low refractive layers 521 and the second high refractive layers 522 may each independently include a non-metallic inorganic material; the second low refractive layers 521 may have a refractive index of about 1.20 to about 1.60, and the second high refractive layers 522 may have a refractive index of about 1.70 to about 2.10. In addition, a thickness t₅₂₁ of each of the second low refractive layers 521 may be smaller than a thickness t₅₂₂ of each of the second high refractive layers 522.

In some embodiments, the second wavelength-selective reflector 520 may have a stacked structure of an odd number of layers. When the second low refractive layers 521 and the second high refractive layers 522 are stacked alternately, a lowest layer of the second wavelength-selective reflector 520, which is in contact with the overcoat layer 260, and a highest layer of the second wavelength-selective reflector 520, which is in contact with the color conversion pattern 230, may have the same refractive index. Since the lowest and highest layers of the second wavelength-selective reflector 520 have the same refractive index, the second wavelength-selective reflector 520 can have efficient (or suitable) reflection and transmission characteristics. For example, since the lowest layer of the second wavelength-selective reflector 520, which is in contact with the overcoat layer 260, and the highest layer of the second wavelength-selective reflector 520, which is in contact with the color conversion layer 230, are all formed as the second high refractive layers 522 having a relatively high refractive index, both the reflection characteristic and transmission characteristic of the second wavelength-selective reflector 520 can be maximized (or improved).

In an embodiment, a total thickness t₅₂₀ of the second wavelength-selective reflector 520 may be greater than a total thickness t₄₁₀ of the first wavelength-selective reflector 410. In addition, the thickness t₅₂₁ of each of the second low refractive layers 521 of the second wavelength-selective reflector 520 may be greater than the thickness t₄₁₁ of each of the first low refractive layers 411 of the first wavelength-selective reflector 410, and the thickness t₅₂₂ of each of the second high refractive layers 522 of the second wavelength-selective reflector 520 may be greater than the thickness t₄₁₂ of each of the first high refractive layers 412 of the first wavelength-selective reflector 410. In some embodiments, the number of layers of the second wavelength-selective reflector 520 may be greater than the number of layers of the first wavelength-selective reflector 410. The reflection wavelength bands and the transmission wavelength bands of the first wavelength-selective reflector 410 and the second wavelength-selective reflector 520 can be controlled by configuring the first wavelength-selective reflector 410 and the second wavelength-selective reflector 520 and the thicknesses and numbers of the layers 411, 412, 521 and 522 constituting the first and second wavelength-selective reflectors 410 and 520 as described above.

In FIGS. 3 through 5, the second wavelength-selective reflector 520 is composed of five layers including three second high refractive layers 522 and two second low refractive layers 521. However, embodiments are not limited to this case, and the second wavelength-selective reflector 520 can be composed of ten or more layers, thirteen or more layers, or fifteen or more layers.

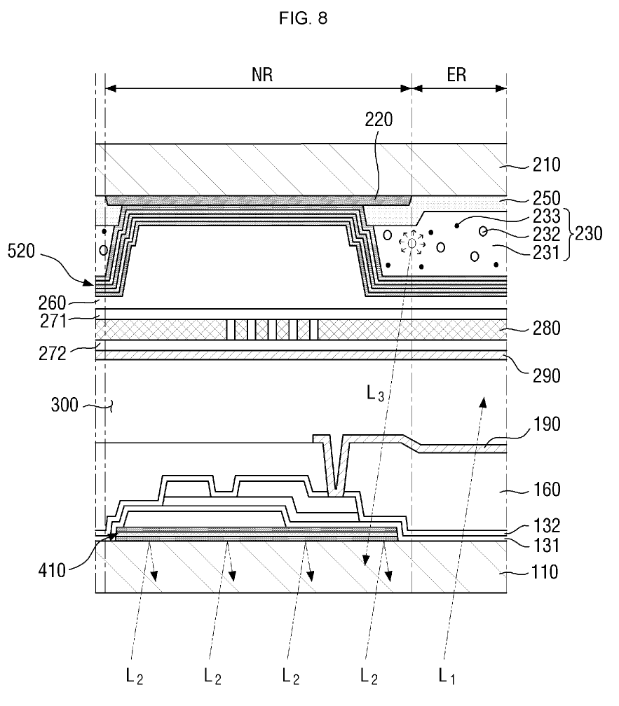

The function of the first wavelength-selective reflector 410 of the display device 1 according to the current embodiment will now be described in more detail by additionally referring to FIG. 8. FIG. 8 is a view that exemplifies the function of a wavelength-selective reflector of the display device 1 of FIG. 2.

Referring to FIGS. 1 through 8, the backlight unit BLU may provide light L₁ and L₂ of the blue wavelength band toward the display panel DP. At least a portion L₁ of the light provided from the backlight unit BLU may be incident on an effective transmissive area ER, and the other portion L₂ may be incident on a non-effective transmissive area NR. The effective transmissive area ER is an area substantially overlapping the pixel electrode 190 and is an area in which the liquid crystals 305 can be rearranged by an electric field formed by the pixel electrode 190 and the common electrode 290. The non-effective transmissive area NR is an area substantially corresponding to the wirings 121 and 151 and the switching element TFT and is an area in which the rearrangement of the liquid crystals 305 cannot be controlled.

At least a portion of the light L₁ in the blue wavelength band incident on the effective transmissive area ER may pass through the liquid crystal layer 300 and travel toward the color conversion pattern 230. The light L₁ incident on the effective transmissive area ER may contribute to image display and color display in the first pixel PX1.

On the other hand, the light L₂ in the blue wavelength band incident on the non-effective transmission area NR may be reflected and thus blocked by the first wavelength-selective reflector 410. This can prevent or reduce the risk of light being transmitted through the non-effective transmissive area NR of the display device 1 to be leaked. The blue light reflected by the first wavelength-selective reflector 410 may be recycled and directed back toward the display panel DP. Thus, light utilization efficiency can be improved.

At least a portion L₃ of red light emitted from the wavelength shifter 232 of the color conversion pattern 230 may pass through the liquid crystal layer 300 to proceed toward the lower substrate 11 without being completely blocked by the second wavelength-selective reflector 520. If the red light L₃ traveling toward the lower substrate 11 is unintentionally reflected again toward the upper substrate 21, a color mixing defect in which the red light L₃ is visible in another pixel may occur. However, since the first wavelength-selective reflector 410 of the display device 1 according to the current embodiment can transmit the red light L₃ emitted from the wavelength shifter 232, the occurrence of the color mixture defect can be prevented or reduced.

For example, the lower substrate 11 of the display device 1 according to the current embodiment includes the first wavelength-selective reflector 410 which reflects light in the blue wavelength band and transmits light in other wavelength bands. Therefore, it is possible to prevent or reduce light leakage, increase light utilization efficiency, and minimize or reduce color mixing.

Hereinafter, other embodiments will be described. For simplicity, a duplicative description of elements identical to those of the display device 1 according to the above-described embodiment will not be provided, and descriptions of the identical elements should be clearly understood by those skilled in the art from the attached drawings.

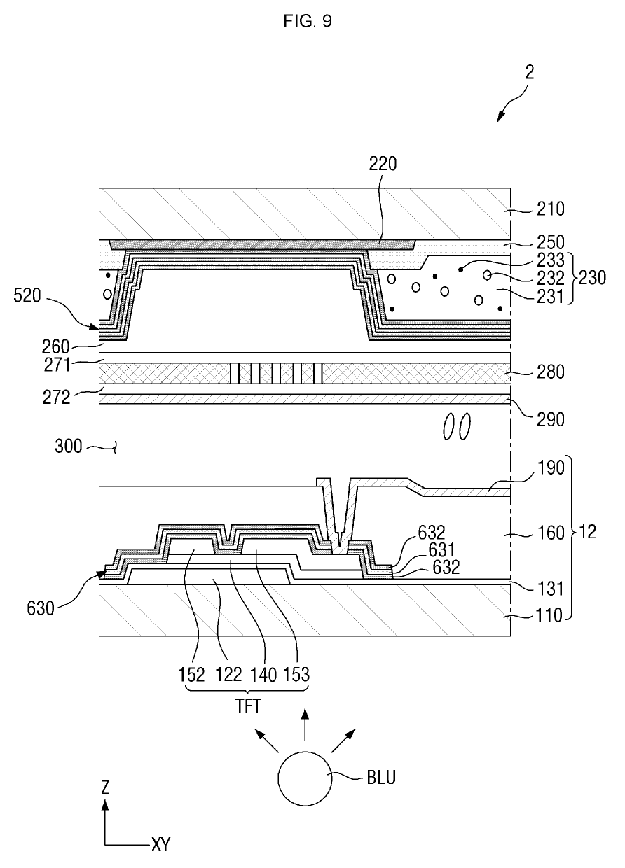

FIG. 9 is a cross-sectional view of a display device 2 according to an embodiment, corresponding to FIG. 4.

Referring to FIG. 9, the display device 2 according to the current embodiment is different from the display device 1 according to the embodiment of FIG. 4 in that a lower substrate 12 does not include a wavelength-selective reflector disposed between a lower base 110 and a switching element TFT, but it includes a third wavelength-selective reflector 630 disposed on the switching element TFT.

In an embodiment, the third wavelength-selective reflector 630 may be disposed on a second wiring layer 152 and 153. For example, the third wavelength-selective reflector 630 may be disposed on a drain electrode 152 and a source electrode 153 and may be in contact with one or more of the drain electrode 152, the source electrode 153 and an active pattern 140. When the third wavelength-selective reflector 630 is an inorganic stack composed only of non-metallic inorganic materials, a protective layer (e.g., the first protective layer 132 of FIG. 4) for protecting the switching element TFT may be omitted.

The third wavelength-selective reflector 630 may be a wavelength-selective optical filter that transmits light of a specific wavelength band and reflects light of another specific wavelength band to block the transmission of the light. For example, the third wavelength-selective reflector 630 may transmit 90% or more of light of a specific wavelength and reflect 90% or more of light of another specific wavelength among light in a visible light wavelength band. In an embodiment, the third wavelength-selective reflector 630 may substantially reflect light in a blue wavelength band and transmit light in other wavelength bands. For example, a reflection peak wavelength of the third wavelength-selective reflector 630 may be within the range of about 430 nm to about 470 nm. In addition, a transmission wavelength band of the third wavelength-selective reflector 630 may include a wavelength band of about 540 nm to about 550 nm and a wavelength band of about 610 nm to about 640 nm.

Although not represented in a plan view, the third wavelength-selective reflector 630 may have substantially the same planar shape as the first wavelength-selective reflector 410 of FIG. 4. That is, the third wavelength-selective reflector 630 may be disposed over a plurality of pixels and may include a first portion extending in the first direction X and a second portion extending in the second direction Y. Thus, the third wavelength-selective reflector 630 may have a substantially lattice shape in plan view. The third wavelength-selective reflector 630 may overlap wirings (a gate wiring and a data wiring) and the switching element TFT. In addition, the third wavelength-selective reflector 630 may completely cover the wirings (the gate wiring and the data wiring) and the switching element TFT. For example, the third wavelength-selective reflector 630 may cover sidewalls of a gate electrode 122, sidewalls of the active pattern 140, sidewalls of the drain electrode 152, and sidewalls of the source electrode 153.

Like the first wavelength-selective reflector 410 of FIG. 4, the third wavelength-selective reflector 630 may have a stacked structure of a plurality of layers. In an embodiment, the third wavelength-selective reflector 630 may be a stack of one or more third low refractive layers 631 and one or more third high refractive layers 632 stacked alternately. For example, the third wavelength-selective reflector 630 may be an optical stack composed only of one or more third low refractive layers 631 and one or more third high refractive layers 632. The third low refractive layers 631 may have a refractive index relatively lower than that of the third high refractive layers 632, and the third high refractive layers 632 may have a refractive index relatively higher than that of the third low refractive layers 631. In addition, the third low refractive layers 631 and the third high refractive layers 632 may each include a non-metallic inorganic material. A thickness of each of the third low refractive layers 631 may be smaller than a thickness of each of the third high refractive layers 632.

In some embodiments, the third wavelength-selective reflector 630 may have a stacked structure of an odd number of layers. When the third low refractive layers 631 and the third high refractive layers 632 are stacked alternately, a lowest layer of the third wavelength-selective reflector 630 (which is in contact with the drain electrode 152, the source electrode 153, and the active pattern 140) and a highest layer of the third wavelength-selective reflector 630 (which is in contact with a step compensating layer 160) may have the same refractive index. For example, the lowest and highest layers of the third wavelength-selective reflector 630 may both be formed as the third high refractive layers 632 having a relatively high refractive index.

In FIG. 9, the third wavelength-selective reflector 630 is composed of three layers including two third high refractive layers 632 and one third low refractive layer 631. However, embodiments are not limited to this case.

The third wavelength-selective reflector 630 may have a contact hole into which a pixel electrode 190 is inserted. The contact hole formed in the third wavelength-selective reflector 630 may be connected to a contact hole formed in the step compensating layer 160. The pixel electrode 190 may be electrically connected to the source electrode 153 of the switching element TFT via the contact hole formed in the step compensating layer 160 and the contact hole formed in the third wavelength-selective reflector 630. For example, the pixel electrode 190 may contact the step compensating layer 160, the third wavelength-selective reflector 630, and the source electrode 153.

Other features of the third wavelength-selective reflector 630 may be substantially the same as those of the first wavelength-selective reflector 410 of FIG. 4, and thus a redundant description thereof will not be provided. In addition, the relationship between the third wavelength-selective reflector 630 and a second wavelength-selective reflector 520 may be substantially the same as the relationship between the first wavelength-selective reflector 410 and the second wavelength-selective reflector 520 of FIG. 4, and thus a redundant description thereof will not be provided.

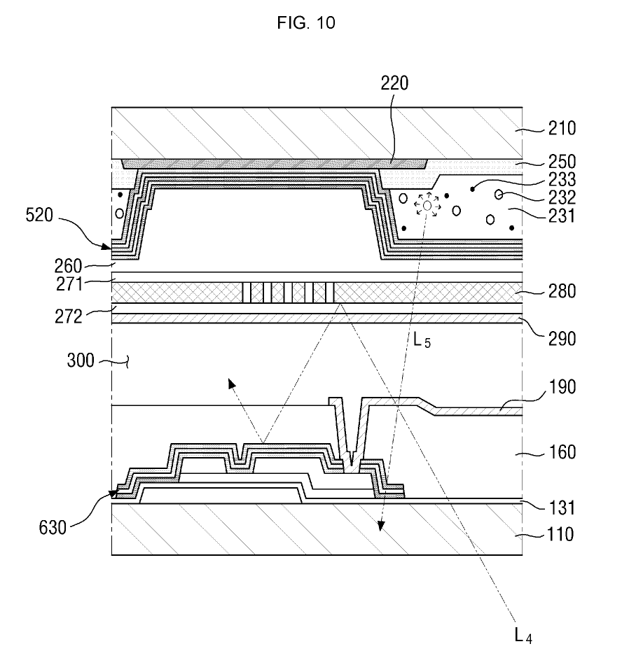

The function of the third wavelength-selective reflector 630 of the display device 2 according to the current embodiment will now be described in more detail by additionally referring to FIG. 10. FIG. 10 is a view for explaining the function of a wavelength-selective reflector of the display device 2 of FIG. 9.

Referring to FIGS. 9 and 10, a backlight unit BLU may provide light L₄ of the blue wavelength band toward a display panel. At least a portion L₄ of the light provided from the backlight unit BLU may travel in an oblique direction to a plane and may be unintentionally reflected by an element, for example, a reflective polarizing layer 280 in the display panel toward the lower substrate 12. In this case, the blue light L₄ reflected by the polarizing layer 280 may travel toward an element, for example, the active pattern 140 of the switching element TFT in the display panel, and cause deterioration of the active pattern 140. If the active pattern 140 including a semiconducting material is exposed to the blue light L₄ for a long time, the off voltage (Voff) and/or threshold voltage (Vth) characteristics of the switching element TFT may deteriorate. However, the third wavelength-selective reflector 630 of the display device 2 according to the current embodiment can block the transmission of the blue light L₄ reflected by the polarizing layer 280 and improve the durability and reliability of the switching element TFT. In addition, the blue light L₄ reflected by the third wavelength-selective reflector 630 can travel toward a color conversion pattern 230 of an upper substrate and contribute to color display, thereby improving light utilization efficiency. Also, in one or more embodiments, the third wavelength-selective reflector 630 can prevent or reduce light leakage by blocking (or substantially blocking) the transmission of blue light incident on a non-effective transmissive area.

At least a portion L₅ of red light emitted from a wavelength shifter 232 of the color conversion pattern 230 may pass through a liquid crystal layer 300 to proceed toward the lower substrate 12 without being completely blocked by the second wavelength-selective reflector 520. Since the third wavelength-selective reflector 630 of the display device 2 according to the current embodiment can transmit the red light L₅ emitted from the wavelength shifter 232, the occurrence of a color mixture defect due to reflected red light can be prevented or reduced.

For example, the lower substrate 12 of the display device 2 according to the current embodiment includes the third wavelength-selective reflector 630 which reflects light in the blue wavelength band and transmits light in other wavelength bands. Therefore, it is possible to prevent or reduce light leakage and increase light utilization efficiency. In addition, it is possible to prevent or reduce deterioration of the active pattern 140 and minimize or reduce color mixing.

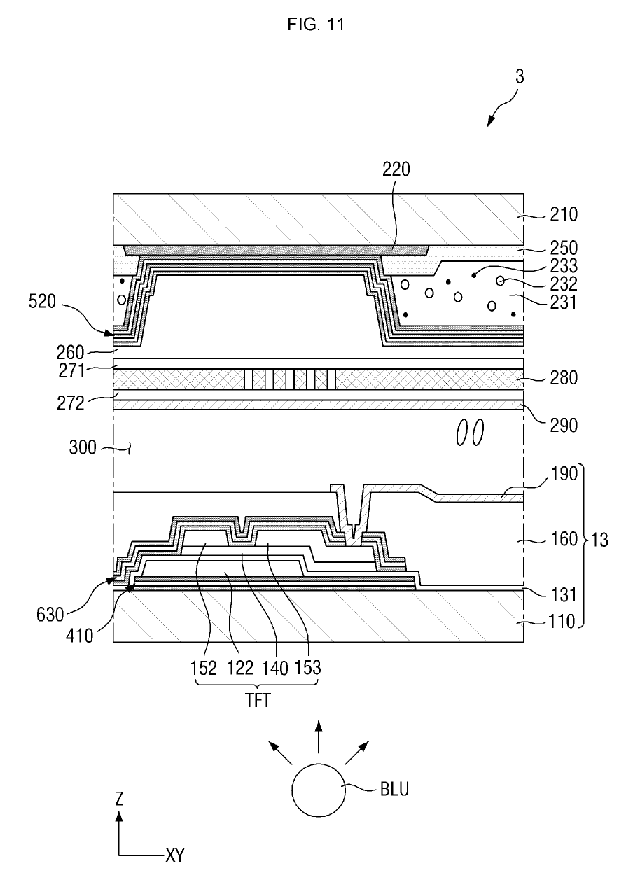

FIG. 11 is a cross-sectional view of a display device 3 according to an embodiment, corresponding to FIG. 4.

Referring to FIG. 11, the display device 3 according to the current embodiment is different from the display device 1 according to the embodiment of FIG. 4 in that a lower substrate 13 includes a first wavelength-selective reflector 410 disposed between a lower base 110 and a switching element TFT and further includes a third wavelength-selective reflector 630 disposed on the switching element TFT.

The first wavelength-selective reflector 410 and the third wavelength-selective reflector 630 may overlap wirings (a gate wiring and a data wiring) and the switching element TFT. In addition, the first wavelength-selective reflector 410 and the third wavelength-selective reflector 630 may completely cover the wirings (the gate wiring and the data wiring) and the switching element TFT.

In an embodiment in which a protective layer (e.g., the first protective layer 132 of FIG. 4) for protecting the switching element TFT is omitted, a gate insulating layer 131 may be in contact with the first wavelength-selective reflector 410 and the third wavelength-selective reflector 630. Specifically, the gate insulating layer 131 may be in contact with a first high refractive layer of the first wavelength-selective reflector 410 and a third high refractive layer of the third wavelength-selective reflector 630.

Since other features of the third-wavelength-selective reflector 630 have been described above with reference to FIG. 9, etc., a redundant description thereof will not be provided.

The display device 3 according to the current embodiment can prevent or reduce light leakage, color mixing, and deterioration of characteristics of the switching element TFT by including both the first wavelength-selective reflector 410 (covering the switching element TFT from under) and the third wavelength-selective reflector 630 (covering the switching element TFT from above).

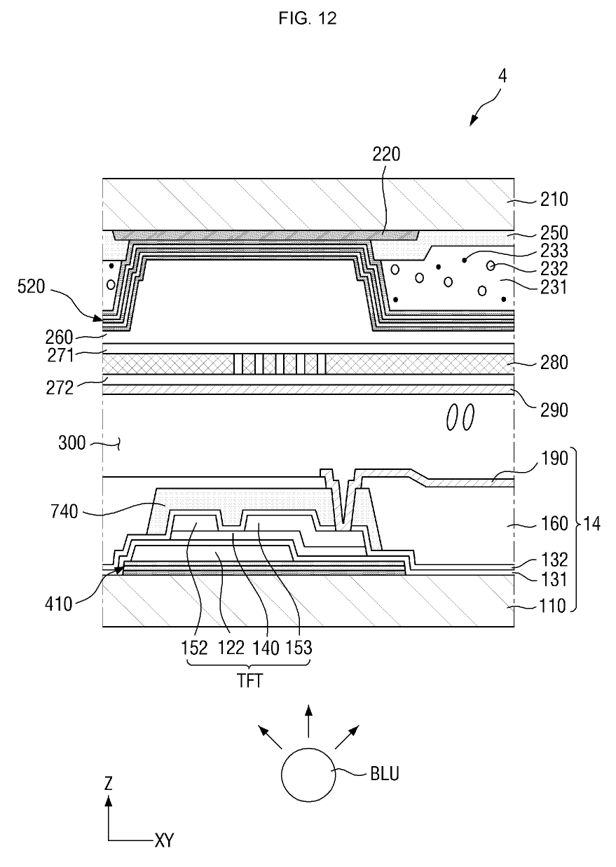

FIG. 12 is a cross-sectional view of a display device 4 according to an embodiment, corresponding to FIG. 4.

Referring to FIG. 12, the display device 4 according to the current embodiment is different from the display device 1 according to the embodiment of FIG. 4 in that a lower substrate 14 further includes a second wavelength-selective transmitter 740 disposed on a switching element TFT.

The second wavelength-selective transmitter 740 may be a wavelength-selective optical filter that transmits light in a specific wavelength band and absorbs or reflects light in another specific wavelength band to block the transmission of the light. For example, the second wavelength-selective transmitter 740 may be a color filter that absorbs light in a blue wavelength band and transmits light in a green wavelength band and/or light in a red wavelength band. For example, an absorption peak wavelength of the second wavelength-selective transmitter 740 may be in the range of about 430 nm to about 470 nm. In addition, a transmission wavelength band of the second wavelength-selective transmitter 740 may be in the range of about 540 nm to about 550 nm or in the range of about 610 nm to about 640 nm. In an embodiment, an absorption wavelength band of the second wavelength-selective transmitter 740 may partially overlap the reflection wavelength band of the first wavelength-selective reflector 410.

The second wavelength-selective transmitter 740 may overlap a channel region formed by the switching element TFT, for example, an active pattern 140 of the switching element TFT. As such, the second wavelength-selective transmitter 740 may fill a space between a drain electrode 152 and a source electrode 153. In an embodiment in which a backlight unit BLU provides light in the blue wavelength band, at least a portion of the light in the blue wavelength band may be reflected by an element, for example, a reflective polarizing layer 280 in a display panel, and cause deterioration of the active pattern 140. The second wavelength-selective transmitter 740 of the display device 4 according to the current embodiment can block (or substantially block) the transmission of the blue light reflected by the polarizing layer 280 and improve the durability and reliability of the switching element TFT.

In some embodiments, the second wavelength-selective transmitter 740 may have a contact hole into which a pixel electrode 190 is inserted. The contact hole formed in the second wavelength-selective transmitter 740 may be connected to a contact hole formed in a step compensating layer 160 and a contact hole formed in a first protective layer 131. The pixel electrode 190 may be electrically connected to the switching element TFT via the contact hole formed in the step compensating layer 160, the contact hole formed in the second wavelength-selective transmitter 740, and the contact hole formed in the first protective layer 131. For example, the pixel electrode 190 may contact the step compensation layer 160, the second wavelength-selective transmitter 740, the first protective layer 131, and the source electrode 153.

A method of manufacturing a wiring substrate according to the inventive concept will now be described.

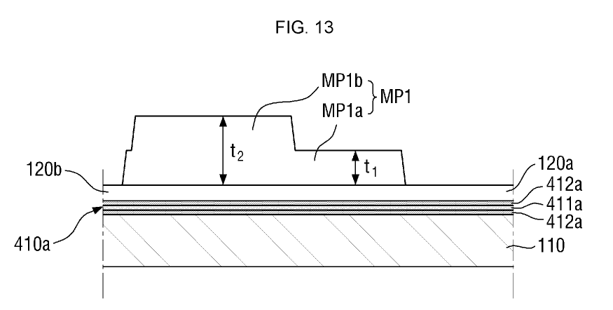

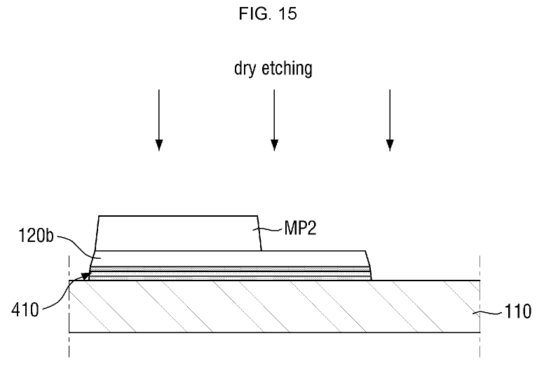

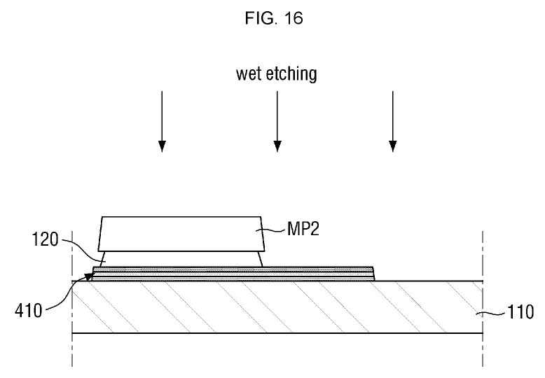

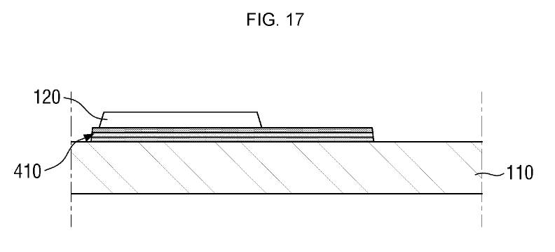

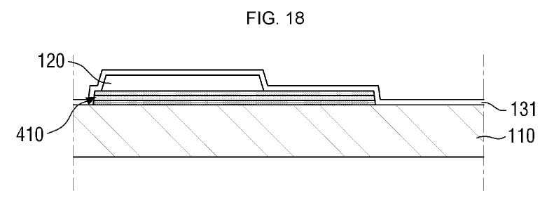

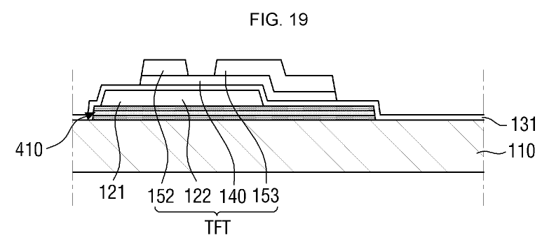

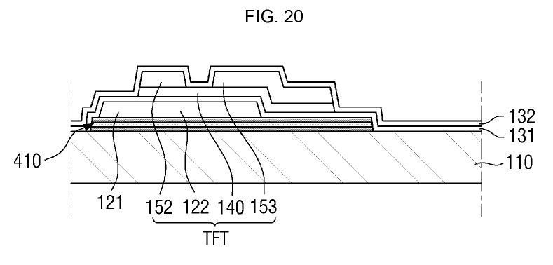

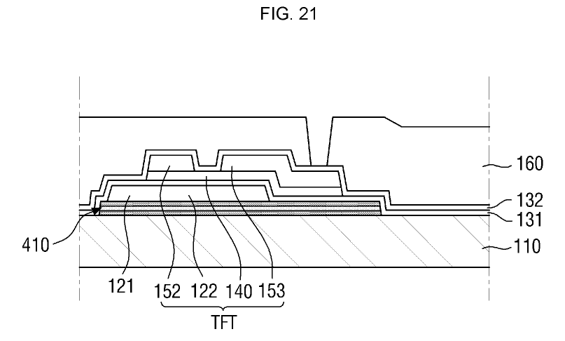

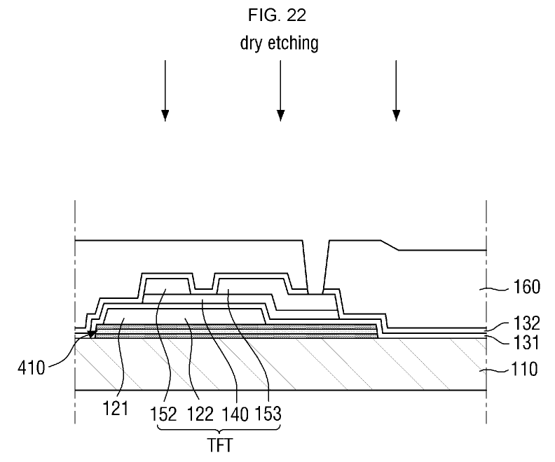

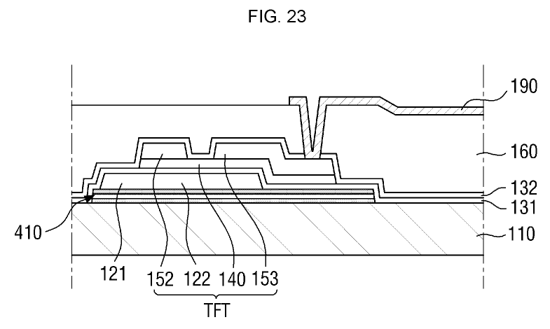

FIGS. 13 through 23 are cross-sectional views corresponding to FIG. 4 and illustrating a method of manufacturing a wiring substrate according to an embodiment.

Referring to FIG. 13, a wavelength-selective reflective layer 410a is formed on a lower base 110, a conductive metal layer 120a is formed on the wavelength-selective reflective layer 410a, and a first mask pattern MP1 is formed on the conductive metal layer 120a.

The wavelength-selective reflective layer 410a may be configured to transmit light in a specific wavelength band and reflect light in another specific wavelength band to block the transmission of the light. For example, the wavelength-selective reflective layer 410a may substantially reflect light in a blue wavelength band and transmit light in other wavelength bands.

The wavelength-selective reflective layer 410a may have a stacked structure of a plurality of layers. In an embodiment, the wavelength-selective reflective layer 410a may be a stack of one or more low refractive layers 411a and one or more high refractive layers 412a stacked alternately. For example, the wavelength-selective reflective layer 410a may be a stack composed only of one or more low refractive layers 411a and one or more high refractive layers 412a. The low refractive layers 411a and the high refractive layers 412a may each include a non-metallic inorganic material. In this case, the wavelength-selective reflective layer 410a may be an inorganic stack composed of only non-metallic inorganic materials. Examples of the non-metallic inorganic materials include silicon nitride, silicon oxide, silicon nitride oxide, and silicon oxynitride, but are not limited thereto.

In addition, a thickness of each of the low refractive layers 411a may be smaller than a thickness of each of the high refractive layers 412a. In some embodiments, the wavelength-selective reflective layer 410a may have a stacked structure of an odd number of layers. When the low refraction layers 411a and the high refraction layers 412a are stacked alternately, a lowest layer and a highest layer of the wavelength-selective layer 410a may have the same refractive index. As shown in FIG. 13, for example, the wavelength-selective layer 410a is composed of three layers including two high refractive layers 412a and one low refractive layer 411a. However, embodiments are not limited to this case.

The conductive metal layer 120a may be formed directly on the wavelength-selective reflective layer 410a. In one or more embodiments, the conductive metal layer 120a may have a stacked structure of two or more layers. Examples of the metallic material that forms the conductive metal layer 120a include titanium, molybdenum, aluminum, copper, silver, and gold, but are not limited thereto.

The first mask pattern MP1 may be placed to expose at least a portion of the conductive metal layer 120a. In addition, the first mask pattern MP1 may have a partially different thickness. In an embodiment, the first mask pattern MP1 may include a first portion MP1a having a first thickness t₁ and a second portion MP1b having a second thickness t₂ greater than the first thickness t₁. The first mask pattern MP1 may include an organic material. The method of forming the first mask pattern MP1 having the first portion MP1a and the second portion MP1b is not particularly limited. For example, the first mask pattern MP1 may be formed by partially exposing and curing a positive photosensitive material or a negative photosensitive material using a three tone mask.

Although embodiments are not limited to the following case, the planar shape of the second portion MP1b of the first mask pattern MP1 may substantially correspond to the planar shape of a first wiring layer 120 including a gate wiring 121 and a gate electrode 122, and the planar shape of the entire first mask pattern MP1 including the first portion MP1a and the second portion MP1b may substantially correspond to the planar shape of a wavelength-selective reflector 410.

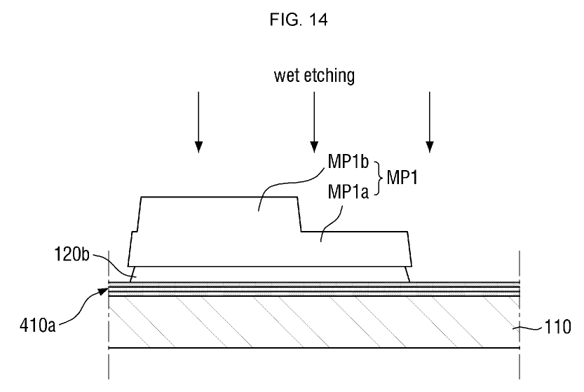

Next, referring to FIGS. 13 and 14, a conductive metal pattern 120b is formed by patterning the conductive metal layer 120a using the first portion MP1a and the second portion MP1b of the first mask pattern MP1 as an etch mask.

In an embodiment, the forming of the conductive metal pattern 120b may be performed through a wet etching process. A portion of the conductive metal layer 120a that is not covered by the first mask pattern MP1 may be etched away by an etchant to form the conductive metal pattern 120b having a shape substantially corresponding to that of the first mask pattern MP1. In addition, as the conductive metal layer 120a is partially removed, the wavelength-selective reflective layer 410a disposed under the conductive metal layer 120a may be at least partially exposed. If each of the conductive metal layer 120a and the conductive metal pattern 120b is composed of a plurality of layers, the layers may all be etched in this operation.

Next, referring to FIGS. 13 through 15, the wavelength-selective reflector 410 is formed by patterning the wavelength-selective reflective layer 410a using the first mask pattern MP1 and the conductive metal pattern 120b as an etch mask. The wavelength-selective reflector 410 may have a stacked structure of a plurality of layers and may be an inorganic stack pattern composed of only non-metallic inorganic materials. Since the wavelength-selective reflector 410 formed in this operation has been described above with reference to FIG. 4, for example, a redundant description thereof will not be provided.

In an embodiment, the forming of the wavelength-selective reflector 410 may be performed through a dry etching process. A portion of the wavelength-selective reflective layer 410a that is not covered by the first mask pattern MP1 and the conductive metal pattern 120b may be removed to form the wavelength-selective reflector 410 having a shape substantially corresponding to that of the conductive metal pattern 120b. In addition, as the wavelength-selective reflective layer 410a is partially removed, the lower base 110 disposed under the wavelength-selective reflective layer 410a may be at least partially exposed.

In the forming of the wavelength-selective reflector 410 through dry etching, the first mask pattern MP1 as well as the wavelength-selective reflective layer 410a may be etched to form a second mask pattern MP2. For example, the relatively thin first portion MP1a of the first mask pattern MP1 may be at least partially removed. Accordingly, the conductive metal pattern 120b overlapped by the first portion MP1a may be exposed. In addition, the relatively thick second portion MP1b of the first mask pattern MP1 may be reduced in thickness to form the second mask pattern MP2 and may remain on the conductive metal pattern 120b.

Next, referring to FIGS. 13 through 16, the first wiring layer 120 is formed by patterning the conductive metal pattern 120b using the second mask pattern MP2 as an etch mask. The first wiring layer 120 may be a gate wiring layer including the gate wiring 121 and the gate electrode 122. Since the first wiring layer 120 has been described above with reference to FIG. 4, for example, a redundant description thereof will not be provided.

In an embodiment, the forming of the first wiring layer 120 may be performed through a wet etching process. A portion of the conductive metal pattern 120b that is not covered by the second mask pattern MP2 may be etched away by an etchant to form the first wiring layer 120 having a shape substantially corresponding to that of the second mask pattern MP2. In addition, as the conductive metal pattern 120b is partially removed, the lower wavelength-selective reflector 410 disposed under the conductive metal pattern 120b may be at least partially exposed. Accordingly, the planar area occupied by the wavelength-selective reflector 410 may be larger than the planar area occupied by the first wiring layer 120, and the wavelength-selective reflector 410 may completely cover the first wiring layer 120.

Next, referring to FIGS. 13 through 17, the second mask pattern MP2 remaining on the first wiring layer 120 is removed. The removing of the second mask pattern MP2 may be performed through, but not limited to, a dry etching process or an ashing process.

Next, referring to FIGS. 13 through 18, an insulating layer 131 is formed on the first wiring layer 120. The insulating layer 131 may be a gate insulating layer that insulates the gate electrode 122 of the first wiring layer 120 from an active pattern 140.

Next, referring to FIGS. 13 through 19, the active pattern 140, a drain electrode 152, and a source electrode 153 are formed on the insulating layer 131. In an embodiment, the active pattern 140, the drain electrode 152, and the source electrode 153 may be etched using a mask pattern having a partially different thickness. As described above, the gate electrode 122 of the first wiring layer 120, the active pattern 140, the drain electrode 152 and the source electrode 153 may form a switching element TFT. In one or more embodiments, the drain electrode 152 and the source electrode 153 may be formed together with a data wiring.

Next, referring to FIGS. 13 through 20, a protective layer 132 is formed on the drain electrode 152 and the source electrode 153. The protective layer 132 may include an inorganic material. The protective layer 132 may include, for example, silicon nitride, silicon oxide, silicon nitride oxide, and/or silicon oxynitride.

Next, referring to FIGS. 13 through 21, an organic layer 160 having a contact hole is formed on the protective layer 132. The organic layer 160 may be a step compensating layer having a step compensating function and an insulating characteristic. The material of the organic layer 160 is not particularly limited. For example, the organic layer 160 may include an organic material such as acrylic resin, epoxy resin, imide resin, and/or cardo resin. The contact hole of the organic layer 160 may expose a portion of the protective layer 132.

Next, referring to FIGS. 13 through 22, a contact hole is formed in the exposed protective layer 132 by using the organic layer 160 as an etch mask. In an embodiment, the forming of the contact hole in the protective layer 132 may be performed through a dry etching process. In addition, since the contact hole is formed in the protective layer 132 by partially removing the protective layer 132 using the organic layer 160 as an etch mask, inner walls of the contact hole of the organic layer 160 may be aligned with inner walls of the contact hole of the protective layer 132. The contact hole of the organic layer 160 and the contact hole of the protective layer 132 may be connected to each other and may partially expose the source electrode 153.

Next, referring to FIGS. 13 through 23, a pixel electrode 190 is formed on the organic layer 160. The pixel electrode 190 may be inserted into the contact holes formed in the organic layer 160 and the protective layer 132 to contact the source electrode 153.

The method of manufacturing a wiring substrate according to the current embodiment can reduce manufacturing cost by patterning the wavelength-selective reflector 410 first, and then the first wiring layer 120 disposed on the wavelength-selective reflector 410 by using the first mask pattern MP1 having a partially different thickness. For example, a lower pattern (i.e., the wavelength-selective reflector 410) having a large planar area and an upper pattern (i.e., the first wiring layer 120) having a small planar area can be formed using only one mask pattern.

The wiring substrate, the display device including the same, and the method of manufacturing the wiring substrate according to the present embodiments, may provide for a display device having improved display quality and durability.

However, the effects of the embodiments of the present disclosure are not restricted to those set forth herein. The above and other effects of the present embodiments will become more apparent to one of ordinary skill in the art to which the embodiments pertain by referring to the present claims.

While the present invention has been particularly illustrated and described with reference to example embodiments thereof, it will be understood by those of ordinary skill in the art that various changes in form and detail may be made therein without departing from the spirit and scope of the present invention as defined by the following claims and their equivalents. The example embodiments described herein should be considered in a descriptive sense only and not for purposes of limitation.

What is claimed is:

1. A display device comprising:
a wiring substrate;
a color conversion substrate on the wiring substrate and comprising a color conversion pattern having a wavelength shifter; and
a backlight unit spaced apart from the color conversion substrate with the wiring substrate interposed between the backlight unit and the color conversion substrate,
wherein the wiring substrate comprises:
a first base;
a thin film transistor on the first base and comprising a gate electrode, an active pattern on the gate electrode, and a drain electrode and a source electrode on the active pattern and spaced apart from each other; and
a wavelength-selective reflector on the first base and stacked with the thin film transistor.

2. The display device of claim 1, wherein the wavelength-selective reflector is composed of non-metallic inorganic materials, and
the wavelength-selective reflector is in contact with one or more of the gate electrode, the active pattern, the drain electrode and the source electrode.

3. The display device of claim 1,
wherein the wiring substrate further comprises a gate wiring connected to the gate electrode and extending in a first direction, and a data wiring connected to the drain electrode and extending in a second direction crossing the first direction, and
the wavelength-selective reflector comprises a first portion which extends in the first direction and at least partially overlaps the gate wiring, and a second portion which extends in the second direction and at least partially overlaps the data wiring,
wherein a width of the first portion of the wavelength-selective reflector in the second direction is greater than a width of the gate wiring in the second direction, and
a width of the second portion of the wavelength-selective reflector in the first direction is greater than a width of the data wiring in the first direction.

4. The display device of claim 1,
wherein the wavelength-selective reflector comprises a first wavelength-selective reflector disposed between the first base and the gate electrode,
wherein the first wavelength-selective reflector is configured to transmit light of a first wavelength in a visible light wavelength band and reflect light of a second wavelength, different from the first wavelength, in the visible light wavelength band to block transmission of light.

5. The display device of claim 4, further comprising a liquid crystal layer between the wiring substrate and the color conversion substrate,
wherein the color conversion substrate comprises:
a second base,
the color conversion pattern on the second base, and
a second wavelength-selective reflector between the color conversion pattern and the liquid crystal layer.

6. The display device of claim 5, wherein the color conversion substrate further comprises a reflective polarizing layer between the second wavelength-selective reflector and the liquid crystal layer.

7. The display device of claim 5,
wherein a reflection wavelength band of the first wavelength-selective reflector is at least partially different from a reflection wavelength band of the second wavelength-selective reflector.

8. The display device of claim 5, wherein a reflection peak wavelength of the first wavelength-selective reflector is shorter than a reflection peak wavelength of the second wavelength-selective reflector.

9. The display device of claim 5,
wherein a transmission wavelength band of the first wavelength-selective reflector at least partially overlaps a reflection wavelength band of the second wavelength-selective reflector,
a reflection peak wavelength of the first wavelength-selective reflector is in the range of about 430 nm to about 470 nm, and
the backlight unit is configured to emit blue light having a peak wavelength in the range of about 430 nm to about 470 nm.

10. The display device of claim 5,
wherein the first wavelength-selective reflector comprises one or more first low refractive layers and one or more first high refractive layers stacked on each other, and
the second wavelength-selective reflector comprises one or more second low refractive layers and one or more second high refractive layers stacked on each other,
wherein a total thickness of the second wavelength-selective reflector is greater than a total thickness of the first wavelength-selective reflector.

11. The display device of claim 5,
wherein the first wavelength-selective reflector comprises one or more first low refractive layers and two or more first high refractive layers stacked on each other, and
the second wavelength-selective reflector comprises one or more second low refractive layers and two or more second high refractive layers stacked on each other,
wherein a refractive index of each of the second low refractive layers is substantially equal to a refractive index of each of the first low refractive layers,
a thickness of each of the second low refractive layers is greater than a thickness of each of the first low refractive layers,
a refractive index of each of the second high refractive layers is substantially equal to a refractive index of each of the first high refractive layers,
a thickness of each of the second high refractive layers is greater than a thickness of each of the first high refractive layers,
one of the first high refractive layers of the first wavelength-selective reflector is in contact with the gate electrode, and
one of the second high refractive layers is in contact with the color conversion pattern.

12. The display device of claim 5, wherein the first wavelength-selective reflector has a stacked structure of an odd number of layers, and
the second wavelength-selective reflector has a stacked structure of an odd number of layers,
wherein the number of layers of the second wavelength-selective reflector is greater than the number of layers of the first wavelength-selective reflector.

13. The display device of claim 5, wherein the color conversion substrate further comprises a light shielding pattern which at least partially overlaps the first wavelength-selective reflector and the second wavelength-selective reflector.

14. The display device of claim 5, wherein the wiring substrate further comprises a wavelength-selective transmitter between the thin film transistor and the liquid crystal layer,
wherein the wavelength-selective transmitter is configured to transmit light of a third wavelength in a visible light wavelength band and absorb light of a fourth wavelength, different from the third wavelength, in the visible light wavelength band to block transmission of the light, and
an absorption wavelength band of the wavelength-selective transmitter at least partially overlaps a reflection wavelength band of the first wavelength-selective reflector.

15. The display device of claim 1, wherein the wavelength-selective reflector comprises a third wavelength-selective reflector on the drain electrode and the source electrode and having a contact hole exposing a portion of the source electrode, and
the wiring substrate further comprises a step compensating layer on the third wavelength-selective reflector, the step compensating layer having a contact hole connected to the contact hole of the third wavelength-selective reflector to expose a portion of the source electrode and
a pixel electrode on the step compensating layer and in contact with the source electrode, the third wavelength-selective reflector and the step compensating layer.

16. The display device of claim 1,
wherein the wavelength-selective reflector comprises:
a first wavelength-selective reflector between the first base and the gate electrode and
a third wavelength-selective reflector on the drain electrode and the source electrode, and
the wiring substrate further comprises a gate insulating layer between the gate electrode and the active pattern, the gate insulating layer being in contact with the first wavelength-selective reflector and the third wavelength-selective reflector.

17. A wiring substrate comprising:
a base;
a thin film transistor on the base and comprising a gate electrode, an active pattern on the gate electrode, and a drain electrode and a source electrode on the active pattern and spaced apart from each other; and
a wavelength-selective reflector on the base and stacked with the thin film transistor.

18. A method of manufacturing a wiring substrate, the method comprising:
forming an inorganic stack of a plurality of layers on a base;
forming a conductive metal layer on the inorganic stack;
forming a first mask pattern on the conductive metal layer;
forming an inorganic stack pattern by patterning the inorganic stack;
forming a gate wiring layer by patterning the conductive metal layer after the forming of the inorganic stack pattern; and
forming an active pattern, a drain electrode and a source electrode on the gate wiring layer.

19. The method of claim 18, wherein the first mask pattern comprises a first portion having a first thickness and a second portion having a second thickness greater than the first thickness, and
the forming of the inorganic stack pattern comprises:
forming a conductive metal pattern by primary etching the conductive metal layer through wet etching by using the first portion and the second portion of the first mask pattern as an etch mask; and
etching the inorganic stack through dry etching by using the first portion and the second portion of the first mask pattern and the conductive metal pattern as an etch mask.

20. The method of claim 19, wherein,
in the forming of the inorganic stack pattern through dry etching,
the first portion of the first mask pattern is at least partially removed to form a second mask pattern which partially exposes the conductive metal pattern, and
the forming of the gate wiring layer by patterning the conductive metal layer comprises forming the gate wiring layer by secondary etching the conductive metal pattern through wet etching by using the second mask pattern as an etch mask.
